(19) United States
(12) Patent Application Publication
(10) Pub. No.: US 2010/0288539 A1
(43) Pub. Date: Nov. 18, 2010

(54) PRINTED WIRING BOARD AND MANUFACTURING METHOD OF THE SAME

(75) Inventor: Mineo WASHIMA, Tokyo (JP)

Correspondence Address: Fleit Gibbons Gutman Bongini & Bianco PL, 21355 EAST DIXIE HIGHWAY, SUITE 115, MIAMI, FL, 33180, US

(73) Assignee: HITACHI CABLE LTD., Tokyo (JP)

(21) Appl. No.: 12/777,296

(22) Filed: May 11, 2010

(30) Foreign Application Priority Data
May 12, 2009 (JP) 2009-115442

(51) Int. Cl. H05K 1/02; H05K 3/02

(52) U.S. Cl. 174/254; 29/846; 174/250

(57) ABSTRACT

A printed wiring board is provided, having conductor patterns formed on a surface of an insulating substrate, wherein the conductor pattern is formed by lamination of a base metal pattern formed by patterning a base metal film which is formed on a surface of the insulating substrate, and plating a metal pattern formed on the base metal pattern by selective plating after the base metal pattern is formed.

### BACKGROUND

1. Technical Field

The present invention relates to a printed wiring board and a manufacturing method of the same, and for example, relates to a printed wiring board particularly suitable for a flexible printed wiring board and a TAB tape having conductive patterns such as wiring patterns on a surface of a liquid crystal polymer film substrate, and a manufacturing method of the same.

2. Description of Related Art

A printed wiring board, being a main essential part of a wiring circuit component of an electronic device is generally broadly divided into a rigid printed wiring board type with conductive patterns such as wiring patterns formed on the surface of, for example, a hard insulating substrate like a glass epoxy substrate, and a flexible printed wiring board type with conductive patterns formed on the surface of, for example, an insulating film base rich in flexibility like a polyimide film.

In recent years, in a further broad field, the flexible printed wiring board and a tape carrier, being one kind of a specific printed wiring board which is thinner and smaller than the flexible printed wiring board, have been used.

In manufacturing such a printed wiring board, a metal-clad substrate such as a so-called copper-clad substrate is used, which is formed by adhering a conductor metal foil such as copper (Cu) foil on the surface of the insulating substrate, or by forming a conductor metal film thereon by electroless plating, etc. In a case of the copper-clad substrate, patterning is applied to a conductor metal layer made of copper (Cu) by etching, etc, and a desired each kind of conductor pattern such as wiring patterns and joint pads is formed, to thereby form a main essential part of the printed wiring board.

In a manufacturing method of a conventional general printed wiring board, first, the surface of the metal-clad substrate is coated with photoresist made of photosensitive resin, or a sheet-like photoresist is adhered thereto. Thereafter, the photoresist is exposed to light by an exposure device and photomask, etc, and is developed, then the surface of the conductor metal layer, which is a part to be removed, is exposed, and a part to be remained as a conductor pattern is set in a state of being covered with its photoresist patterns. Then, the part in the metal conductor layer not covered with photoresist and exposed, is removed by etching, to set the remained part as the conductor pattern. Thereafter, an unnecessary photoresist pattern is removed (dissolved and peeled, etc,) by using a fluxing material, etc. Such a subtractive method has been frequently used in the manufacturing method of a conventional printed wiring board.

In recent years, in a field of the flexible wiring board and the TAB tape, etc, also, as the electronic device becomes smaller and a wiring density is more increased, further finer tendency of the conductor patterns are accelerated, and a relative thickness of the conductor metal layer to a line width (namely aspect ratio) is more increased.

Therefore, in a patterning process by the subtractive method, it is further difficult to respond to a technical request which is close to a processing limit by etching such as about 15 μm of line width and space of the wiring patterns, and about 30 μm of a wiring pitch, because an etching factor such as side etching becomes a constraint.

As a technique for precisely forming the conductor patterns responding to such a finer conductor patterns, patent document 1 discloses a method of performing patterning by removing a part of a sputter metal film by using a laser, and patent document 2 discloses a method of achieving a thick film by depositing and coating a plating layer by plating on the surface of the conductor patterns, after the conductor patterns are formed by removing a part of a sputter conductor film by laser.

Further, there is also a conductor pattern forming method of an additive system such as a fully additive method and a semi-additive method, as one of the important methods of precisely forming extremely fine conductor patterns responding to such a finer conductor patterns (conductor patterns of a high aspect ratio in many cases) (for example, see patent documents 3 and 4).

The fully additive method is a method of forming desired conductor patterns by selectively adhering the conductor metal film to the surface of the insulating substrate by electroless plating, with a resist of low adhesion property used as a resist.

Further, the semi-additive method is a method of forming a base metal film of 1 μm or less made of conductor metal such as copper (Cu) on the surface of the insulating substrate by, for example, a sputtering process, etc, and coating the surface of the base metal film with photoresist to expose and develop the photoresist, to thereby form resist patterns, and forming each kind of conductor pattern such as desired wiring patterns and land patterns based on the resist patterns by electrolytic plating and electroless plating, by using the conductor metal film of an exposed part not covered with the resist patterns as a seed layer of plating, and using the resist patterns that cover a part where patterning is not necessary as a barrier of plating (plating resist) (Patent document 5).

Conventionally, generally the additive method has a problem that its manufacturing process is complicated compared with that of the subtractive method, thus making it difficult to simplify the manufacturing process and reduce a manufacturing cost, and a problem that an adhesion property of the conductor patterns composed of the conductor film, to the insulating substrate of conductor patterns is low. However, in recent years, the adhesion property has been improved mainly in the semi-additive method.

### (Related Art Documents)

### (Patent Document 1)

Japanese Patent Publication No. 3493703 (Patent document 2)

### Japanese Patent Laid Open Publication No. 1992-263490

(Patent document 3)

### Japanese Patent Laid Open Publication No. 1973-25866

(Patent document 4)

### Japanese Patent Laid Open Publication No. 1977-19263

(Patent document 5)

### Japanese Patent Laid Open Publication No. 2003-37137

However, in the semi-additive method, the conductor patterns such as wiring patterns are formed by electrolytic plating and electroless plating, and thereafter a resist between the conductor patterns is peeled once, and an unnecessary seed layer remained between the conductor patterns is removed by so-called slight etching, to thereby perform wiring isolation. Therefore, the number of manufacturing steps is increased, resulting in complicated manufacturing process, thereby increasing a manufacturing cost as a whole.

Further, when the unnecessary seed layer between the conductor patterns is removed by etching, the surface of the conductor patterns is also removed by at least a thickness portion of the seed layer, and therefore error is generated in the shape and the dimension of the finished conductor patterns, by this removed portion. In addition, in recent years, tendency of further finer wiring patterns (further finer line and space) is accelerated. Therefore, there is a higher possibility that shape reproducibility and dimension accuracy of the conductor patterns are damaged by generation of the error.

It can also be considered that the generation of the error is predicted in advance, and correction expecting such an error may be performed to a design dimension of the conductor patterns and process conditions. However, it is extremely difficult to perform exact correction expecting the error in advance, because the tendency of further finer wiring patterns is accelerated, and actually various factors are entangled with each other to cause an overall error to be generated in the finished conductor patterns.

Thus, in the conventional printed wiring board and the manufacturing method of the same, in particularly a case of the semi-additive system, we can respond to further finer wiring and further higher aspect ratio, and the adhesion property of the conductor patterns to the surface of the insulating board has been improved. However, in its manufacturing process, particularly there is the step of removing the unnecessary seed layer by etching, thus involving a problem that its manufacturing step is complicated and the cost is increased. This problem is unsolved.

Further, there is a problem that when the unnecessary seed layer between wiring is removed by etching, the surface of the conductor patterns is also etched to make patterns narrower and thinner, thereby decreasing the shape reproducibility and the dimension accuracy of the conductor patterns in the finished printed wiring board.

### SUMMARY OF THE INVENTION

An object of the present invention is to provide the printed wiring board capable of forming fine conductor patterns easily and with high precision, and the manufacturing method of the same.

An aspect of the printed wiring board of the present invention provides a printed wiring board having a conductor pattern formed on a surface of an insulating substrate, wherein the conductor pattern is formed by lamination of a base metal pattern formed by patterning a base metal film which is formed on a surface of the insulating substrate, and a plating metal pattern formed on the base metal pattern by selective plating after the base metal pattern is formed.

An aspect of a manufacturing method of a printed wiring board of the present invention includes the steps of:
forming a base metal pattern on a surface of an insulating substrate;
coating the surface with a negative photoresist, where the metal pattern is formed;
forming a plating resist pattern on the insulating substrate in such a way that the insulating substrate is irradiated with light so as to transmit therethrough from a surface of the opposite side to the surface of the insulating substrate, and the negative photoresist of a part, where the base metal pattern is not formed, is irradiated with the transmitted light and is exposed with the base metal patterns as a self-alignment mask, and thereafter is developed; and
forming a metal pattern selectively on the base metal pattern by plating the surface of the base metal pattern of a part where the plating resist pattern is not formed.

### BRIEF DESCRIPTION OF THE DRAWINGS

FIG. 1 is a sectional view showing a structure of a main essential part of a printed wiring board according to an embodiment of the present invention.

FIG. 2 is a plan view showing the structure of a main essential part of a printed wiring board according to an embodiment of the present invention.

FIG. 3A to FIG. 3F are views showing flows of main essential steps in a manufacturing method of a printed wiring board according to an embodiment of the present invention.

### BEST MODE FOR CARRYING OUT THE INVENTION

A printed wiring board and a manufacturing method of the same according to preferred embodiments of the present invention will be described hereinafter, with reference to the drawings.

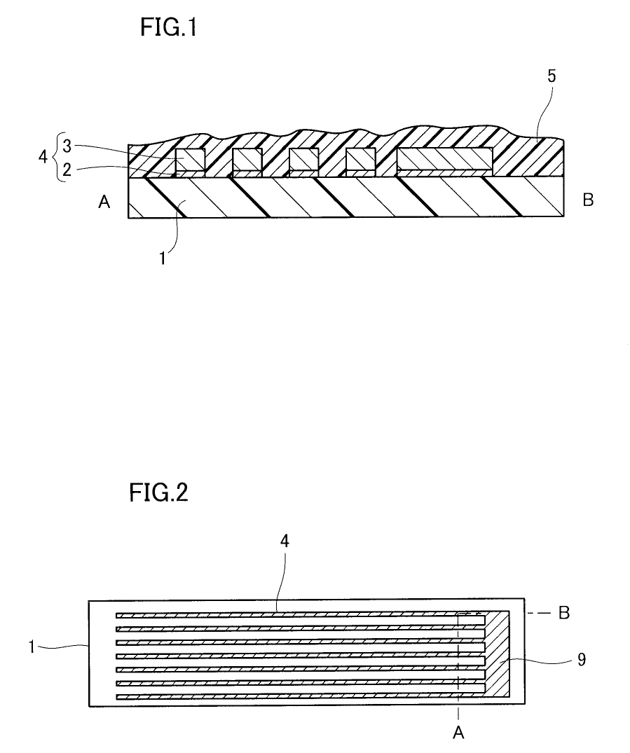

As shown in FIG. 1, the printed wiring board includes conductor patterns 4 formed on a surface of an insulating substrate 1, by laminating base metal patterns 2 which are formed by patterning a base metal film, and plating metal patterns 3 which are formed by selective plating on the base metal patterns 2 after pattern formation of the base metal patterns 2. Then, a solder resist 5 is formed so as to cover substantially an entire surface of the surface of the insulating substrate 1 on which the conductor patterns 4 are formed.

The insulating substrate 1 has electric insulating property, and has optical transparency for transmitting a light of a photosensitive wavelength range of a photoresist 6 as will be described later. As a material of the insulating substrate 1, an important point is that the transparency to the light of the photosensitive wavelength range of the photoresist 6 is high, and from this viewpoint, for example, a liquid crystal polymer (LCP) film having flexibility can be given as a typical example of the material that can be suitably used.

However, of course the insulating substrate 1 is not limited to only the liquid crystal polymer film. Other materials which satisfies the transparency of the photoresist 6 to the light of the photosensitive wavelength rang can also be applicable for the insulating substrate.

Further, in a case of a polyimide film generally and frequently used as an insulating film base material for a tape carrier, although heat resistance property is sufficiently excellent, the optical transparency to g-line (wavelength 436 nm) for photoresist exposure frequently used in forming fine patterns is inferior to that of the liquid crystal polymer film. Therefore, when the polyimide film is used as the insulating substrate 1, there is a high possibility that exposure time of the photoresist 6 is extremely prolonged and fine patterns are hardly formed precisely. From this point, the liquid crystal polymer film is more desirable than the polyimide film, as the material of the insulating substrate 1.

When the polyimide film is used, it is desirable to combine the light having the wavelength with satisfactory transparency to the polyimide film, and the photoresist capable of obtaining an accurate latent image by exposure using the light having this wavelength. Specifically, Kapton and Upilex (registered trademarks), being the polyimide film, have extremely low transmissivity to ultraviolet rays. Therefore, when such a polyimide film is used as the insulating substrate 1, SONNE LDM (Product name by Kansai Paint Company) is used as a negative resist and also argon ion laser (wavelength of 488 nm) is used as a light source for exposure. Alternatively, SONNE LDY (Product name and produced by Kansai Paint Company) is used as the negative resist and also YAG-SHG laser (wavelength 532 nm) is used as the light source for exposure.

Base metal patterns 2 function as a seed layer when metal patterns 3 are formed thereon by an electrolytic plating (electric plating) or an electroless plating. However, the base metal patterns 2 are different from the base metal patterns in a conventional technique (semi-additive method) from the viewpoint that patterning of the base metal patterns 2 are already performed before the plating metal patterns 3 are formed, in an appearance of prescribed pattern. Accordingly, in the base metal patterns 2, the step of removing an unnecessary part by etching is completely eliminated, which is the part other than the parts of the conductor patterns 4 to be remained, or what is called the “wiring isolation” after the plating metal patterns 3 are formed, like a case of the printed wiring board according to the conventional art.

As the material of the base metal patterns 2, for example, noble metals such as silver (Ag), gold (Au), platinum (Pt), palladium (Pd), or copper (Cu), tin (Sn), or nickel (Ni) are preferable, for the reason of exhibiting resistance against oxidation and being easy to be handled as materials. Further, light shielding property or reflection property against the light in the photosensitive wavelength range of the photoresist are likely to be higher on the surface of the metal film made of such metal materials, and therefore these materials can be said to be proper materials as a self-alignment mask in the exposure of the photoresist 6 as will be described later. However, it is a matter of course that the material that can be used as the base metal patterns 2 is not limited to the aforementioned materials. A material capable of forming the seed layer of the plating metal patterns 3 and satisfying conditions of the dimension accuracy and shape reproducibility of required patterning, can be used as the forming material of the base metal patterns 2.

In the formation of the plating metal patterns 3, the photoresist 6 is irradiated with light 7 that transmits through the insulating substrate 1 from the backside of the insulating substrate 1 by using the base metal patterns 2 as a self-alignment mask, to thereby expose and develop the photoresist 6 and form resist patterns 8. Then, by plating only an exposed part not covered with the plating resist patterns 8, with the base metal patterns 2 as a seed layer, selective plating is performed only on the surface of the base metal patterns 2, specifically not on a side surface of the base metal patterns 2 covered with the plating resist patterns 8 but only on an upper surface of the base metal patterns 2.

The plating metal patterns 3 are desirably made of copper (Cu) or copper-based alloy. Further, a plating method used in a forming method of the plating metal patterns 3 may be either an electrolytic plating method or an electroless plating method. From the viewpoint of the throughput in the plating step and from the viewpoint that the plating metal patterns 3 of a prescribed thickness can be formed in a further short time, the electrolytic plating method is more desirable.

The plating metal patterns 3 are selectively and precisely formed only on the surface of the base metal patterns 2 by the aforementioned plating method, and it is not necessary to perform etching for wiring isolation as is described in the conventional art. Therefore, there is completely no cutdown of the patterns due to etching for wiring isolation (meaning a condition in which the patterns are etched to be narrower and thinner), and therefore the plating metal patterns 3 can be formed as precise patterns, in a thickness of not less than 5 times that of the base metal patterns 2.

A condition in which the thickness of the plating metal patterns 3 is set to be not less than 5 times that of the base metal patterns 2, means a condition in which the thickness of the base metal patterns 2 is set to be thinner, such as ⅕ or less of the thickness of the plating metal patterns 3, reversely. Accordingly, from this viewpoint, when the base metal patterns 2 are formed by patterning the base metal film (not shown) by etching, this base metal film is extremely thin such as ⅕ or less of the thickness of the metal patterns 3. Therefore, it is possible to set a minimum line width of the base metal patterns 2 to be extremely small, which are the base metal patterns 2 that can be formed, while securing a prescribed dimension accuracy and shape reproducibility. Further, it is also possible to set the minimum line width of the metal patterns 3 to be extremely small, which are the metal patterns 3 that can be formed on the base metal patterns 2 by self-alignment. As a result, it is also possible to set a minimum line width of the conductor patterns 4 to be extremely small, with high precision or finer patterns are realized.

A main essential part of the conductor patterns 4 in the printed wiring board according to the present invention is constituted by the aforementioned base metal patterns 2 and the metal patterns 3 formed thereon.

Although not shown, it is also possible to further apply coating of tin (Sn) and gold (Au) plating films to the surface of the conductor patterns 4, to improve rust proof performance, reinforcement of a mechanical strength, and to improve connectability to an external device.

Next, a manufacturing method of the printed wiring board according to an embodiment of the present invention will be described.

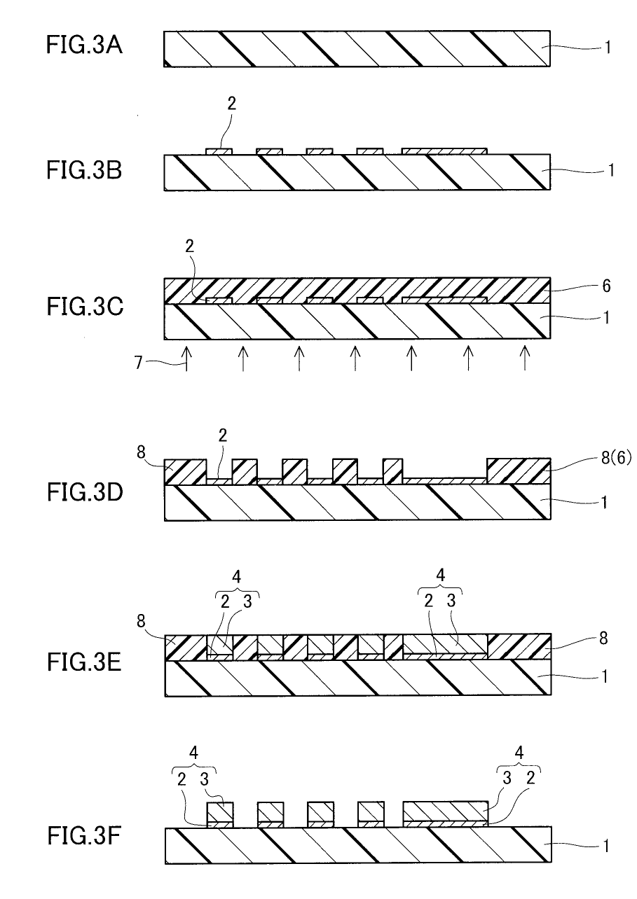

First, as shown in FIG. 3A, the insulating substrate 1 made of a material having good electric insulation property and good transparency to the light of the photosensitive wavelength range of the photoresist 6, for example like a liquid crystal polymer film, is prepared.

Then, as shown in FIG. 3B, the base metal patterns 2 are formed by patterning the base metal film formed on a surface of the insulating substrate 1, for example by etching, etc. Alternatively, the base metal patterns 2 may be formed by a print method using a metal paste as ink.

Subsequently, as shown in FIG. 3C, the negative photoresist 6 is coated on a surface on which the base metal patterns 2 are formed. Then, by irradiation of the light 7 that transmits through the insulating substrate 1, from the surface of the opposite side (namely, the backside) to the surface on which the base metal patterns 2 are formed, exposure of the photoresist 6 is performed, by using the base metal patterns 2 as the self-alignment mask. Thereafter, by developing the photoresist 6 with developer, an exposed part is remained after development, and as shown in FIG. 3D, the plating resist patterns 8 having a reverse pattern of the base metal patterns 2 (pattern corresponding to a part where the base metal patterns 2 do not exist), can be obtained. Namely, the plating resist patterns 8 thus obtained are the patterns in which only the base metal patterns 2 are exposed and the other part is covered.

Subsequently, as shown in FIG. 3E, by using the plating resist patterns 8, the plating metal patterns 3 are formed selectively only on the surface of the base metal patterns 2, by electrolytic plating or electroless plating, with a part where the plating resist patterns 8 are not provided, namely a part of the surface of the base metal patterns 2 not covered with the plating resist patterns 8, used as a seed layer.

Thereafter, by removing (dissolving or peeling, etc,) the already used resist patterns 8, the conductor patterns 4 formed by lamination of the base metal patterns 2 and the plating metal patterns 3, as shown in FIG. 3F can be obtained.

Thus, according to the manufacturing method of the printed wiring board of this embodiment, by irradiation of the light 7 that transmits through the insulating substrate 1, from the surface of the opposite side (namely, the backside) to the surface on which the base metal patterns 2 are formed, the photoresist 6 coated on the surface on which the base metal patterns 2 are formed, is exposed by using the base metal patterns 2 as the self-alignment mask, and the photoresist is further developed to obtain the plating resist patterns 8, and the plating metal patterns 3 are formed selectively only in the part where the plating resist patterns 8 are not formed and the surface of the base metal patterns 2 are exposed. Therefore, it is possible to completely omit the step of removing the unnecessary seed layer as shown in the conventional art by etching. As a result, it is possible to form the conductor patterns 4 including extremely fine wiring patterns in a thickness more than a prescribed thickness, with high precision, so as to respond to the finer conductor patterns in the printed wiring board. Further, it is possible to achieve the simplification of the manufacturing steps and the reduction of the manufacturing cost in association with the simplification of the manufacturing steps.

In addition, it is also possible to form the metal patterns 3 having the thickness of not less than 5 times that of the base metal patterns 2 by plating. Therefore, the conductor patterns 4 formed by lamination of the plating metal patterns 3 and the base metal patterns 2 can be made thick in the high aspect ratio of 1 or more, even in a case of the fine wiring patterns. As a result, conductivity of the conductor patterns 4 can be significantly excellent.

Further, limitation of microfabrication precision of the line width and quality of pattern reproducibility in the conductor patterns 4 are greatly affected by the pattern precision of the base metal patterns 2, being the seed layer of the plating metal patterns 3. However, in the printed wiring board and the manufacturing method of the same according to this embodiment, by making the thickness of the base metal patterns 2 extremely thin such as ⅕ or less of the thickness of the metal patterns 3, it is possible to set the minimum line width of the base metal patterns 2 to be extremely small, which are the base metal patterns 2 that can be formed while securing a prescribed dimension accuracy and shape reproducibility, particularly when the base metal patterns 2 are formed by patterning using the subtractive method such as an etching process. As a result, it is also possible to set the minimum line width of the metal patterns 3 to be extremely small, which are the metal patterns 3 that can be formed on the base metal patterns 2 by self-alignment, and also possible to set the minimum line width of an entire body of the conductor patterns 4 to be extremely small.

Note that in the aforementioned embodiments, the embodiments were described in consideration of a case that the present invention is applied to a tape carrier for a semiconductor device using an insulating film base material such as a liquid crystal polymer film as the insulating substrate 1. However, it is a matter of course that the present invention is not limited to the printed wiring board of such a tape carrier type. Other than the printed wiring board of the tape carrier type, the present invention can also be applied to a flexible printed wiring board using a flexible substrate having flexibility, as the insulating substrate 1, or a rigid printed wiring board using a rigid substrate made of a hard material such as the one forming a glass substrate and a glass epoxy substrate.

### EXAMPLES

Test production of the printed wiring board according examples of the present invention was tried by using the manufacturing method explained in the aforementioned embodiments.

As the insulating substrate 1, the material needs to be selected so as to be suitable for the exposure of the photoresist 6 from the backside. Generally, exposure of a heavily used photoresist is performed by using visible light having a wavelength close to the ultraviolet ray, or ultraviolet ray. Therefore, in this example, in consideration of the aforementioned matter as a prerequisite, a sheet material of liquid crystal polymer is used, having a small dielectric loss tangent tans, and which is suitable as the insulating film base material for a tape carrier type printed wiring board for signal transmission of millimeter waveband. In this example, LCP film (product name VECSTAR by KURARAY Company) having a thickness of 50 μm was used.

Note that it is a matter of course that the material of the insulating substrate 1 is not limited to the liquid crystal polymer, and other than the liquid crystal polymer, it is possible to use materials having good durability in a final use environment, such as PET (Poly Ethylene Terephthalate), PEN (Poly Ethylene Naphthalate), and PE (Poly Ethylene).

When optical wavelength photosensitive characteristics of the photoresist 6 are taken into consideration, g-line (436 nm) is used in many cases, as a light beam for precise patterning of μm level. Therefore, it is desirable to select the insulating substrate 1 based on a viewpoint of good optical transparency to the g-line. Alternatively, other than the g-line, ultraviolet rays such as i-line (365 nm), KrF excimer laser (248 nm), ARF excimer laser (193 nm), F₂ eximer laser (157 nm) are utilized in some cases. However, in these cases also, similarly it is desirable to select the insulating substrate 1 from the viewpoint of whether the good optical transparency can be obtained.

Nanoparticles of silver (Ag) (low temperature sinter type 1-Ag1TeH by ULVAC, Inc.) were applied to a surface of the insulating substrate 1 in a thickness of 100 nm by using an applicator, and by a laser direct drawing method, comb-shaped patterns are sintered as shown in FIG. 2 (FIG. 1 is a developed sectional view of a cross-section taken along the line A-B of FIG. 2), and the unnecessary part was cleaned with organic solvent such as tetradecane, to thereby form the base metal patterns 2.

Here, silver nanoparticles which are relatively easily handled in this example were used. However, as the metal kind of the base metal patterns 2, other than silver (Ag), it is also possible to noble metals such as gold (Au), platinum (Pt), palladium (Pd), and copper (Cu), or metals hardly oxidized such as tin (Sn) and nickel (Ni). Note that it is likely to be extremely difficult to use easily oxidized titanium (Ti), aluminium (Al), and magnesium (Mg), etc.

Further, in this example, the laser drawing method was used, because this is a pattern forming method capable of relatively easily forming the base metal patterns 2 at a narrow wiring pitch. However, generally the laser drawing method is likely to incur high cost in the point of a drawing time and a use efficiency of the ink. Therefore, although the laser drawing method is a good method in terms of not requiring a manufacturing cost in a case of manufacturing a printing plate, it is desirable to form the base metal patterns 2 by using a printing technique such as screen printing and gravure printing capable of performing production at a low cost, with high throughput, in a case of a mass production in a commercial line.

Subsequently, a substantially entire surface on a surface of the insulating substrate 1 including the base metal patterns 2, is coated with a liquid negative resist material ZPN1150 (by ZEON), as the photoresist 6.

In this example, the liquid resist was used, without considering the cost and throughput, because this time is still in the trial phase. However, actually, a long material is processed by reel-to-reel, in a case of the mass production in the so-called commercial line. Therefore, it is desirable to adhere a dry film photoresist (such as SUNFORT (trademark) by Asahi KASEI electronics Inc.) to a surface of the insulating substrate ion which the base metal patterns 2 are formed.

Subsequently, by irradiating the insulating substrate 1 with g-line of wavelength 436 nm from the backside using an ultraviolet ray exposure device, the photoresist 6 was exposed, with the base metal patterns used as the mask pattern of the self alignment. Thereafter, the photoresist 6 was developed, to obtain the plating resist patterns 8.

More specifically, in the exposure step at this time, ultraviolet ray irradiance was set to be 320 mJ and PEB (post-exposure bake) was set to be one minute at 90° C. Then, after PEB, the photoresist was developed for one minute using developer (NMD-3 by TOKYO OHKA KOGYO CO.,) and was cleaned by water. Then, the photoresist 6 was exposed, by using the base metal patterns 2 as the mask pattern of self alignment, to obtain the resist patterns with dimension of the narrowest part of a line-and-space set to be 5 μm.

Note that in this example, in order to form the metal patterns 3 by an electrolytic copper plating method in the next step, as shown in FIG. 2, comb-shaped patterns as a whole were formed, in which a plurality of conductor patterns 4 (substantially wiring patterns) formed in parallel with each other are connected to one conduction pattern 9 in common.

Subsequently, by performing electrolytic plating while supplying prescribed current for plating, with a probe for power supply brought into contact with the conduction pattern 9, copper plating is performed selectively only on the surface of the base metal patterns 2, to thereby form thick metal patterns 3 with a thickness of 5 μm.

Thereafter, the already used plating resist patterns 8 were dissolved and removed by acetone, and a solder resist 5 is formed thereon. Thus the main essential part of the printed wiring board according to this example of the present invention was completed.

The printed wiring board according to this example of the present invention thus manufactured achieves good conductivity by making the plating metal patterns 3 thick such as 5 μm, despite the fact that the conductor patterns 4 are formed at an extremely fine pitch.

Further, in this example, the conduction pattern 9 which was unnecessary after the plating metal patterns 3 were formed, could be easily cut finally in the same way as the case of a general tape carrier, as a part of the peripheral edge part of the insulating substrate 1, and therefore the plating metal patterns 3 could be formed by the electrolytic plating method using such a conduction pattern 9. However, the conduction pattern 9 can not be formed in some cases, depending on a requested overall shape of the conductor patterns 4 and the kind of the printed wiring board. In this case, the metal patterns 3 are formed by electroless plating. In such a case, it is desirable to add 1% or more by weight of the fine particles of palladium (Pd) into the forming material of the base metal patterns 2 (into the ink made of silver nanoparticles paste in this example). Thus, it is possible to improve the accuracy of selectively forming the metal patterns 3 by electroless plating. Alternatively, practically sufficient selectivity can be improved in some cases, even in a case of adding 1% or less by weight.

However, generally there is a high possibility of generating abnormal precipitation in the case of the electroless plating, compared with the case of the electrolytic plating, and in the point of the throughput also, there is such a tendency that the electroless plating is inferior to the electrolytic plating. Therefore, it is more desirable to use the electrolytic plating method than use the electroless plating method, as a plating process for forming the plating metal patterns 3.

What is claimed is:

1. A printed wiring board having a conductor pattern formed on a surface of an insulating substrate, wherein the conductor pattern is formed by lamination of a base metal pattern formed by patterning a base metal film which is formed on the surface of the insulating substrate, and a plating metal pattern formed on the base metal pattern by selective plating after the base metal pattern is formed.

2. The printed wiring board according to claim 1, wherein a thickness of the plating metal pattern is not less than 5 times that of the base metal pattern.

3. The printed wiring board according to claim 1, wherein the insulating substrate is made of a liquid crystal polymer film having flexibility.

4. The printed wiring board according to claim 1, wherein light of g-line is transmitted through the insulating substrate.

5. A manufacturing method of a printed wiring board, comprising the steps of:
forming a base metal pattern on a surface of an insulating substrate;
coating the surface with a negative photoresist, where the metal pattern is formed;
forming a plating resist pattern on the insulating substrate in such a way that the insulating substrate is irradiated with light so as to transmit therethrough from a surface of the opposite side to the surface of the insulating substrate, and the negative photoresist of a part, where the base metal pattern is not formed, is irradiated with the transmitted light and is exposed with the base metal patterns as a self-alignment mask, and thereafter is developed; and
forming a metal pattern selectively on the base metal pattern by plating the surface of the base metal pattern of a part where the plating resist pattern is not formed.

6. The manufacturing method of the printed wiring board according to claim 5, wherein the plating metal pattern is formed in a thickness of not less than 5 times that of the base metal pattern.

7. The manufacturing method of the printed wiring board according to claim 5, wherein the insulating substrate is made of a liquid crystal polymer film having flexibility.

8. The manufacturing method of the printed wiring board according to claim 5, wherein the base metal pattern is formed by pattering a base metal film formed on the surface of the insulating substrate.

9. The manufacturing method of the printed wiring board according to claim 5, wherein the base metal pattern is formed by sintering a prescribed pattern by a laser drawing method, on the surface of the insulating substrate coated with a metal paste.

10. The manufacturing method of the printed wiring board according to claim 5, wherein the base metal pattern is formed on the surface of the insulating substrate, by a printing technique such as screen printing and gravure printing, by using a metal paste as ink.

11. The manufacturing method of the printed wiring board according to claim 5, wherein the base metal pattern includes a metal selected from any one of Ag, Au, Pt, Pd, Cu, Sn, and Ni.

12. The manufacturing method of the printed wiring board according to claim 5, wherein the light that transmits through the insulating substrate to expose the photoresist is g-line.

13. The manufacturing method of the printed wiring board according to claim 5, wherein the plating metal pattern is formed by electrolytic plating.

14. The manufacturing method of the printed wiring board according to claim 5, wherein the plating metal pattern is formed by electroless plating.

15. The manufacturing method of the printed wiring board according to claim 5, wherein the plating metal pattern is made of copper or copper-based alloy.
